(19) United States
(12) Patent Application Publication
(10) Pub. No.: US 2024/0222136 A1
(43) Pub. Date: Jul. 4, 2024

(54) ELECTRICAL LAYER WITH ROUGHENED SURFACES

(71) Applicant: Intel Corporation, Santa Clara, CA (US)

(72) Inventors: Bohan Shan, Chandler, AZ (US); Haobo Chen, Chandler, AZ (US); Srinivas Venkata Ramanuja Pietambaram, Chandler, AZ (US); Hongxia Feng, Chandler, AZ (US); Gang Duan, Chandler, AZ (US); Xiaoying Guo, Chandler, AZ (US); Ashay A. Dani, Chandler, AZ (US); Yiqun Bai, Chandler, AZ (US); Dingying Xu, Chandler, AZ (US); Bai Nie, Chandler, AZ (US); Kyle Jordan Arrington, Gilbert, AZ (US); Wei Wei, Chandler, AZ (US); Ziyin Lin, Chandler, AZ (US)

(21) Appl. No.: 18/091,188

(22) Filed: Dec. 29, 2022

(51) Int. Cl. H01L 21/321; H01L 21/3065; H01L 21/311; H01L 21/768

(52) U.S. Cl. CPC H01L 21/3212; H01L 21/3065; H01L 21/31116; H01L 21/76814; H01L 21/7684

(57) ABSTRACT

Mechanical or chemical processes can form roughened surfaces which can be used for coupling layers of electrical systems such as when forming dies, substrates, computer chips or the like that, when subjected to high stress, are robust enough to remain coupled together.

### TECHNICAL FIELD

This document pertains generally, but not by way of limitation, to electrical devices with layers having exposed areas with roughened surfaces configured for anchoring additional layers or components for use with computer chips, chiplets, or similar electronic components.

### BACKGROUND

Computer chips, and other similar components for electronic systems are formed from layers of materials that are usually stacked or placed one on top of the other. The complexity of computer chips and other similar components necessitates minimal displacement of subsequent layers or electrical, mechanical or electro-mechanical component when coupled to layers, including, for example, but not limited to deformation of adjacent layers, misalignment of layers, movement of layers during assembly. Polymer material is one such material used for a layer on which further layers can be coupled, or components can be coupled. When subsequent layers or components are bonded, adhered or coupled together, epoxies, soldering, or adhesion promoters can be used to couple subsequent layers or components. Forming deformations, irregular surfaces, or rough surfaces on a layer used in an electrical system can improve adhesion.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is an illustration of a cross section of an example layer of an electronic system.

FIG. 2A is an illustration of a cross section of an example layer with a roughened surface.

FIG. 2B is a microscopic view of an example layer with a roughened surface.

FIG. 2C is an illustration of a cross section of an example layer with a roughened surface.

FIGS. 3A-3C are illustrations of a cross sectional views of an example of a process of forming a roughened surface.

FIG. 4A is an illustration of a cross section of an example layer with an exposed surface.

FIG. 4B-4C are a microscopic views of an example layer with a roughened surface.

FIG. 4D is an illustration of a cross section of an example layer with a roughened surface.

FIG. 5A-5C are illustrations of a cross section of an example of a process of forming a roughened surface.

FIGS. 6A and 6B are illustrations of systems with a layer with a roughened surface coupled to a substrate.

FIG. 7 is an illustration of a system level diagram, depicting an example of an electronic system.

### DETAILED DESCRIPTION

Some substrates for computer chips or other electrical systems can be built, formed or otherwise assembled from layers of materials, for example resins, polymers, glass or the like. A resin layer can be made from a polymer resin, glass, or any material suitable for the purpose. The foundation, or base, of these layers can be a core layer on which other layers made from the same or similar materials, or other components of a chip can be coupled, built up, or assembled.

A layer can have a dielectric material, as a layer, or another polymer-based material layer coupled to upper or lower surfaces of a subsequent layer. Electrical, mechanical or electro-mechanical components can be coupled to a surface of a layer. Further, layers can be coupled to the resin core to form stacked layers with electrically conductive interconnects applied, coupled or formed on or to the surfaces of the layers.

Polymer as a layer material and dielectric materials coupled to the resin layers, in some situations, can be a deformable material or can be difficult to couple together. Polymers layers can deform when subjected to applied pressures or when the material is subjected to fluctuations in temperature. Deformations to resin layers and dielectric materials can be expansion or contraction of the material in lateral directions. Deformations can also be caused by compression or expansion in a depth direction. The deformations can also be undulations, ripples or uneven thicknesses in the resin core material. Both applied pressures and temperature fluctuations are known environmental conditions during manufacturing of computer chips which can result in changes in dimensions of at least one resin layer or dielectric material layer. Deformations can result in changes to the location of the components coupled to or formed in or with at least one layer. These types of mechanical displacements can further promote the layers from being coupled together or slipping.

The present inventors have recognized a need for layers within a die, substrate, core or computer chip which can have surfaces which promote adhesion with further layers or additional components when subjected to changes in environmental conditions and does not experience significant changes to material properties. The present inventors have recognized the need for a material for layers or components which can remain substantially constant so any additional components, additional layers, though holes or conductive materials can remain substantially in place.

For example, a strong adhesion strength between material stackups (a plurality of layers coupled together) can be critical for achieving a product reliability target. For example, strong adhesion can be beneficial for coupling between chiplets bonded, coupled or adhered to a base stack or a substrate surface. The present inventors have recognized roughening an exposed surface can be one method to improve adhesion. The present inventors have recognized mechanical processes such as chemical-mechanical polishing (CMP) can be used to roughen an exposed surface of a layer. The present inventors have also recognized chemical processes such as plasma dry etching can be used to roughen an exposed surface of a layer. Either mechanical or chemical processes can form roughened surfaces which can be used for coupling layers that, when subjected to high stress situations, are robust enough to remain coupled together.

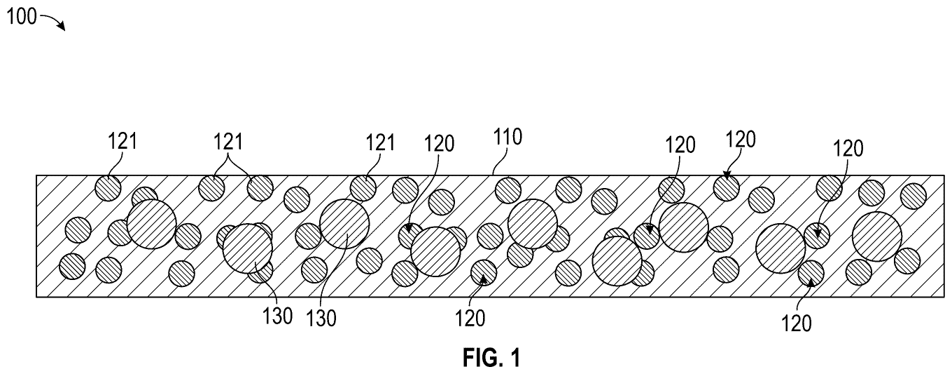

Illustrated in FIG. 1 is an example of a layer 100 that can support a roughened surface configured to have further layers or components coupled or adhered to an exposed surface of the layer 100. In FIG. 1, the exposed surface 110 can be an upper, or first, surface; however, any surface configured to support or be coupled with another layer or component can be roughened. In an example, the layer 100 can be formed with a bulk of nonreactive nano-sized organic particles 120 contemplated by the purpose. The bulk of nano-sized organic particles 120 can be a hydrophilic particle, or molecule, such as water, alcohols, cyclodextrins, or redox-active organometallic compounds or the like. For example, the layer can include a number of bulk of nano-sized organic particles 120 dispersed throughout the layer 100. The bulk of nano-sized organic particles 120 embedded in the layer 100 can be dispersed throughout the layer 100. The bulk of nano-sized organic particles 120 can be dispersed throughout the layer so a plurality of the nano-sized organic particles 121 can be proximate to the exposed surface 110 in addition to throughout the depth of the layer 100.

In an example, a second plurality of fillers 130 can be dispersed throughout the layer in addition to the bulk of nano-sized organic particles 120. The second plurality of fillers 130 can be any additional particle to the layer, such as silica, talc, graphite, glass fibers, or any other filler suitable for the purpose. The second plurality of fillers 130 can be a different filler, such as a hydrophobic particle, or molecule. The second plurality of fillers 130 can be a filler that is not easily removed from the layer 100 during subsequent processes to the layer 100.

The bulk of nano-sized organic particles 120 can be a plurality of particles which can be disposed throughout the layer 100, such as throughout all of the layer 100, substantially all of the layer 100, or a selected region or point on the layer 100. The bulk of nano-sized organic particles 120 can include the plurality of nano-sized organic particles 121 proximate to, adjacent to, or on the exposed surface 110. The plurality of nano-sized organic particles 121 can be reactive to bond with a slurry that can be applied to the exposed surface 110 during a mechanical process.

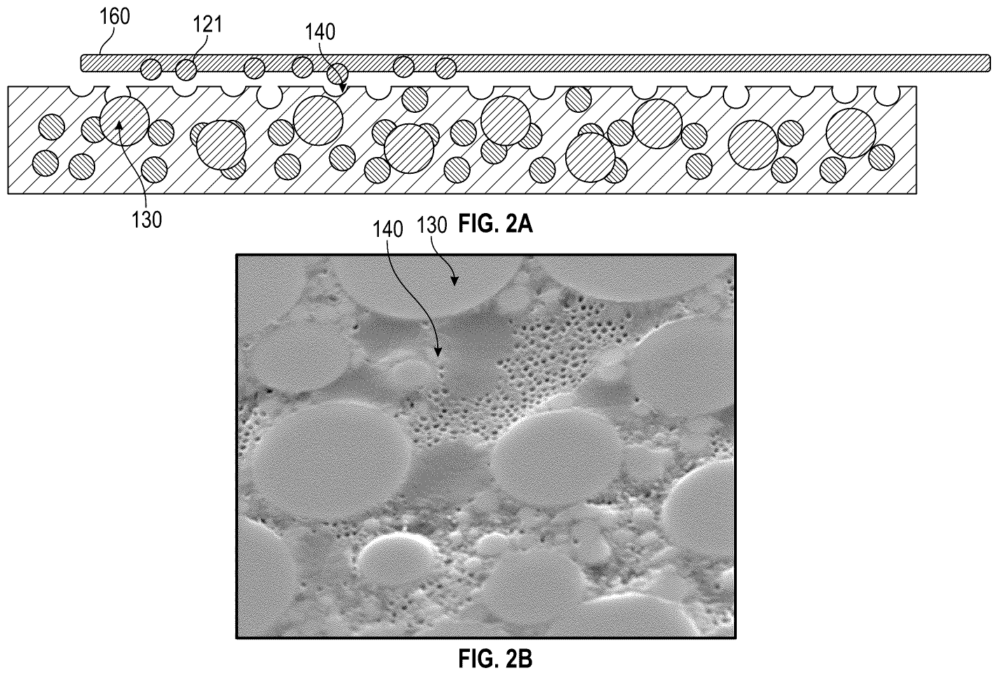

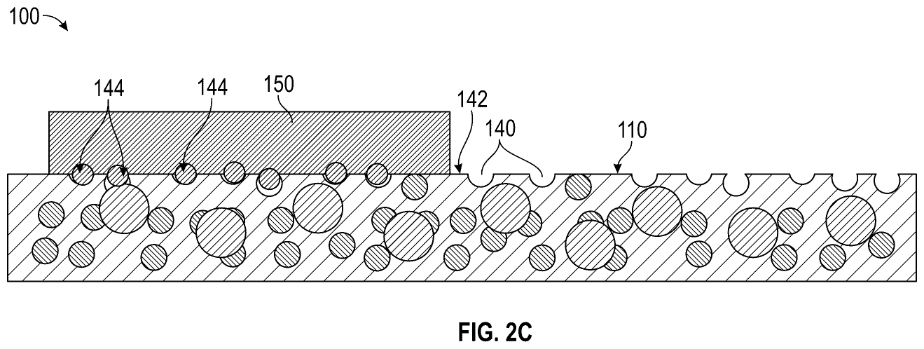

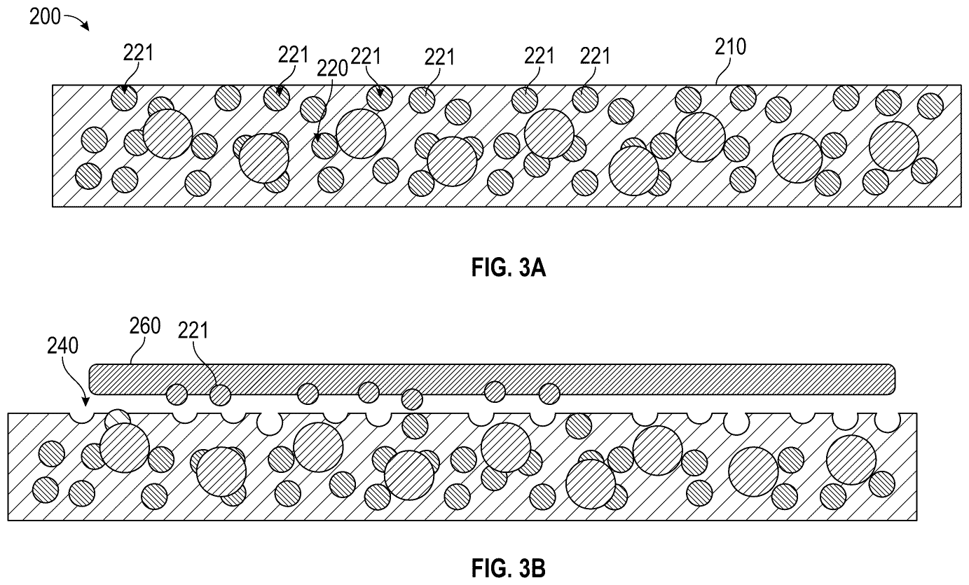

In an example, as illustrated in FIGS. 2A-C, the plurality of nano-sized organic particles 121 can be configured to be reactive to a slurry 160 in a manner that the slurry 160 removes the plurality of nano-sized organic particles 121. The removal of the plurality of nano-sized organic particles 121 can result in the formation of gaps, recesses, cavities, pockets, pin-holes (hereinafter “recesses” 140) or the like in the exposed surface 110 of the layer 100. The recesses 140, such as the geometry of the recesses, can be irregularly shaped and sized. The recesses 140 can form a configuration that is an irregular, roughed surface. The exposed surface 110 with the recesses 140 can, conversely, include a plurality of protrusions 142. The protrusions 142 can spikes, peaks, columns, extensions, projections, or the like (hereinafter protrusions) which can be the remnants of the layer that did not react with the slurry.

The formation of recesses and protrusions can form a rough surface. A rough surface can be a surface which has greater than 50 nm of average roughness. The difference in height, or depth, between adjacent recess and protrusions can be between tens of nanometers to several micrometers in range. Further, for example the range can be from 100 nm to 50 μm. In an example, an average depth of the recesses below the mean line between each protrusion can be from approximately 100 nm to approximately 50 μm. The average distance between the peaks, or conversely the distance between the valleys, can vary, for example between approximately 10 nm to approximately 50 μm.

As illustrated in FIG. 2C, the recesses 140 in combination with the protrusions 142 can be configured to be anchoring points 144. The anchoring points 144 can assist in promoting adhesion between a downstream material 150, such as a dielectric layer, or any other layer or component, that is configured to be coupled to the exposed surface 110. The recesses 140 can be configured to receive adhesives such as epoxy or adhesion promoters or the like which can be deposited, adhered, or the like on the exposed surface to enhance bonding of the downstream material 150 with the layer 100. The adhesives can fill the recesses either partially or completely and form wells where the adhesives can be held and not spread or expand to other surfaces of the layer 100. The recesses 140 can assist in minimizing the possibility of the adhesive failing or not performing as expected.

Returning to FIG. 2B, the roughened surfaces can be detected by viewing a cross section of the layer. For, example using a scanning electron microscope (SEM), the roughened surface can be viewed. In another example energy dispersive x-ray spectroscopy (EDX) can be used as an analytical method for analytical or chemical characterization of materials. The use of a SEM and EDX can be used individually or jointly to detect or view the surface roughness.

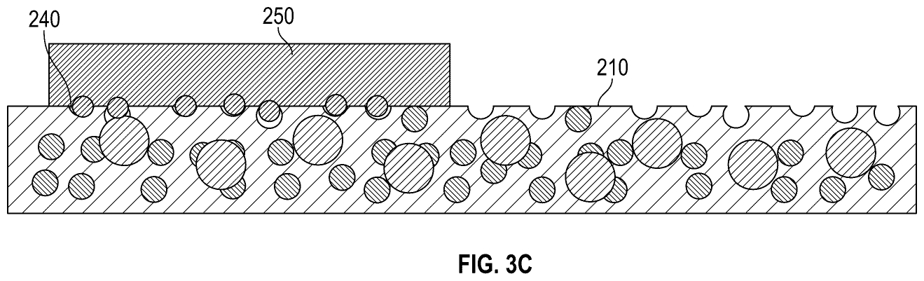

A method of forming recesses 140, as described above, and as illustrated in FIGS. 3A-3C, can include incorporating a plurality of nano-sized organic particles 220 into the layer 200. For example, the plurality of nano-sized organic particles 220 incorporated into the layer 200 can be any plurality of nano-sized organic particles 220 suitable for the purpose. At least some of the plurality of nano-sized organic particles 221 are proximate to an exposed surface 210 of the layer 200.

A slurry 260 can be deposited, formed, spread or otherwise over the exposed surface 210. The slurry 260 can consist of nano-sized abrasive particles that are dispersed in a chemically reactive solution. The nano-sized abrasive particles in the slurry 260 can react with or bind with the plurality of nano-sized organic particles 221. CMP can then be applied to the exposed surface 210 of the layer 200. The CMP can smooth the exposed surface, while the slurry interacting with the exposed surface 210 can form recesses within the exposed surface 210.

As illustrated in FIG. 3B, the slurry 260 can be polished from the exposed surface 210. For example, the nano-sized organic particles can be smeared off during fine grinding or CMP. The slurry 260 will bind with the nano-sized organic particles and remove them from the exposed surface 210. In an example, CMP can be applied to substantially all of the exposed surface 210. CMP can also be applied to only a region of the exposed surface 210 suitable for the purpose. The resulting exposed surface 210 can then have a plurality of irregularly sized recesses. The plurality of recesses 240 can be formed in the exposed surface 210 in a range of depths and profiles. The plurality of recesses 240 can extend at different depths within the exposed surface 210 depending on the location of each of the nano-sized organic particles 221 that were proximate to the exposed surface 210. The exposed surface 210 can be a substantially smooth surface in areas where there are no recesses 240. In another example, the exposed surface 210 can have an irregular surface that is not smooth.

The recesses can behave as nano anchors to assist in increasing the interface adhesion. This process can form physical anchoring points which can improve the adhesion strength without the addition of alternative bulk mechanical properties.

As illustrated in FIG. 3C, a downstream material 250 can be applied, coupled, connected, placed, deposited (hereinafter coupled) or the like to the exposed surface 210. The downstream material 250 can be coupled to the exposed surface 210 at the location where CMP has been applied. The downstream material 250 can be coupled at the areas where recesses 240 can be formed in the exposed surface 210.

The downstream material 250 can be mechanically coupled with the layer 200 using a compressive process. In a mechanical process for coupling the downstream material 250 with the layer 200, the recesses 240 can be anchors where the downstream material 250 can be forced and deformed into. An adhesive material can also be applied between the exposed surface 210 and the downstream material 250. The adhesive material can fill, partially or completely, the recesses and the downstream material can be placed on the adhesive material. The recesses 240 can be configured to be anchoring points of the adhesive in cooperation with the downstream material 250. The coupling of the downstream material 250 in the method described above can be adhered in a secured manner.

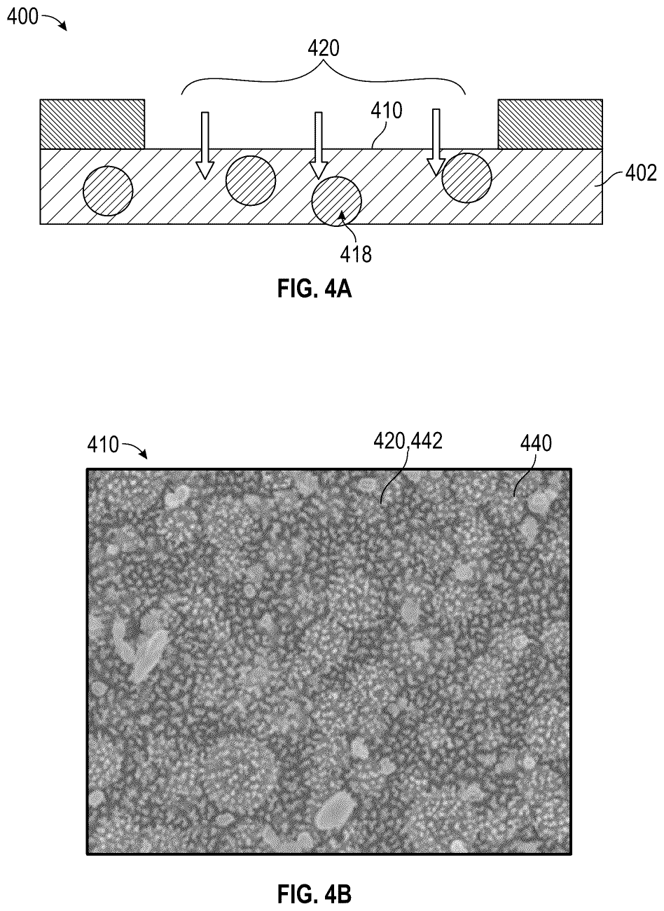

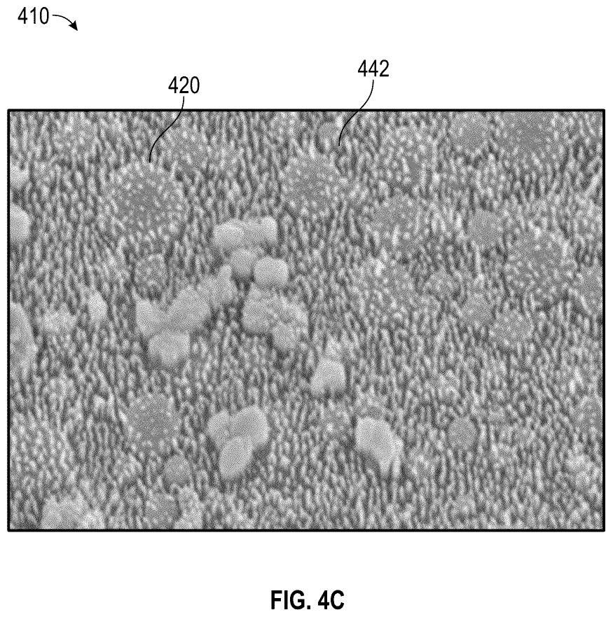

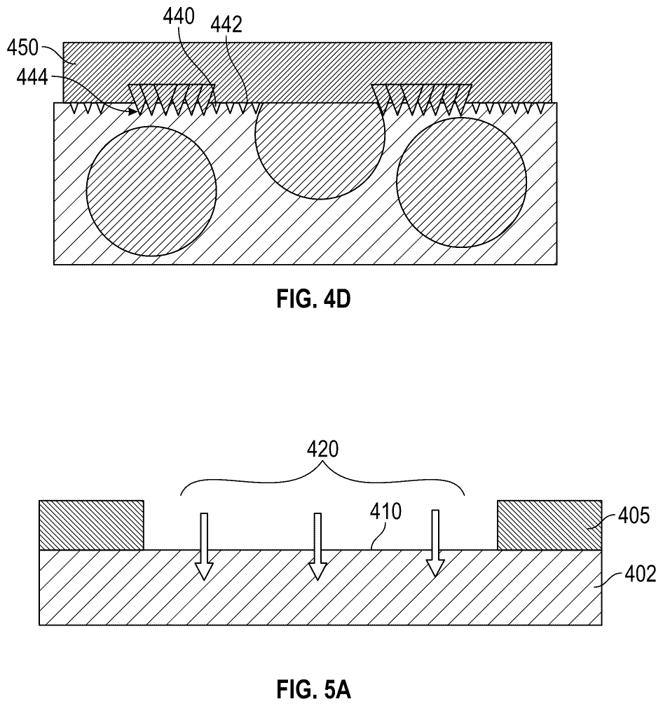

Illustrated in FIG. 4A is an example layer 400. The layer 400 can be a layer used in any electrical system, such as a die package, substrate, chiplet or the like. The layer 400 can also be a solder resist or mold. The layer 400 can have a body 402 which can have a plurality of organic fillers 418 dispersed throughout. The layer 400 can be treated, such as by to an infusion, injection or the like with sodium or magnesium ions 420. The treatment, or contact, with sodium ions or magnesium ions 420 can result in a plurality of sodium ions or plurality of magnesium ions 420 being embedded or absorbed within the layer 400.

The plurality of sodium ions and the plurality of magnesium ions 420 have properties which can be inert to exposure of certain gases. For example, the plurality of sodium ions and the plurality of magnesium ions 420 can be inert to gases used in plasma etching. For example, the plurality of magnesium ions and the plurality of sodium ions can be inert to argon, hydrogen, oxygen, fluorine-based or chlorine-based gases.

The plurality of sodium ions and the plurality of magnesium ions 420 can penetrate partially through a depth of the body 402 of the layer 400. The plurality of sodium ions and the plurality of magnesium ions 420 can penetrate the exposed surface 410 with an average depth of approximately 10 nm to approximately 50 μm.

A roughened exposed surface 410 can be formed on the layer 400 at predetermined locations. In an example, plasma etching can be used to assist in forming a roughened exposed surface 410. The roughened exposed surface 410 can have recesses 440 formed where the material of the layer 400 reacted with the plasma etching. The areas where the plurality of sodium ions or plurality of magnesium ions were absorbed by the material can remain as projections, protrusions, pillars, peaks or the like (hereinafter projections 442). The profile of the recesses 440, such as the geometry, of the recesses can be irregularly spaced. The profile of the recesses 440 can have irregular depths. The cooperation of the projections 442 and the recesses 440 can be configured to be anchor points in the layer 400.

The images of FIGS. 4B and 4C show microscopic views of the exposed surface 410 in areas where the plurality of sodium ions or the plurality of magnesium ions 420 have been absorbed in the material of the layer 400. The recesses 440 are shown in the darker regions of the image. As can be seen in FIGS. 4B and 4C, the exposed surface 410 has an irregular, or roughened geometry.

The formation of recesses and protrusions can form a rough surface. A rough surface can be a surface which has greater than 50 nm of average roughness. The difference in height, or depth, between adjacent recess and protrusions can be between tens of nanometers to several micrometers in range. Further, for example the range can be from 100 nm to 50 μm. In an example, an average depth of the recesses below the mean line between each protrusion can be from approximately 100 nm to approximately 50 μm. The average distance between the peaks, or conversely the distance between the valleys, can vary, for example between approximately 10 nm to approximately 50 μm.

The recesses 440 in combination with the protrusions 442 can be configured to be anchoring points 444, as illustrated in FIG. 4D. The anchoring points 444 can assist in promoting adhesion between a downstream material 450, such as a dielectric layer, or any other layer or component, that is configured to be coupled to the exposed surface 110. The recesses 440 can be configured to receive adhesives such as epoxy or adhesion promoters or the like which can be deposited, adhered, or the like on the exposed surface to enhance bonding of the downstream material 450 with the layer 400. The adhesives can fill the recesses either partially or completely and form wells where the adhesives can be held and not spread or expand to other surfaces of the layer 400. The recesses 440 can assist in minimizing the possibility of the adhesive failing or not performing as expected.

As illustrated in FIGS. 4B and 4C, the roughened surfaces can be detected by viewing a cross section of the layer. For, example using a scanning electron microscope (SEM), the roughened surface can be viewed. In another example energy dispersive x-ray spectroscopy (EDX) can be used as an analytical method for analytical or chemical characterization of materials. The use of a SEM and EDX can be used individually or jointly to detect or view the surface roughness.

In an example, forming a roughened surface at select locations with dry etching can be implemented when assembling wafer-level layers. Forming roughened layers on an exposed surface 410 of a solder resist (as the layer 400) can provide challenges. Using a process such as dry etching, with a photoresist as a means for identifying the location, can assist in forming roughened surfaces at location where capillary underfill is bonded, adhered, coupled or the like, to one side of a silicon die. Locating areas where bonding downstream material specifically with dry etching process can assist in minimizing damage to areas not configured for being coupled with the downstream material.

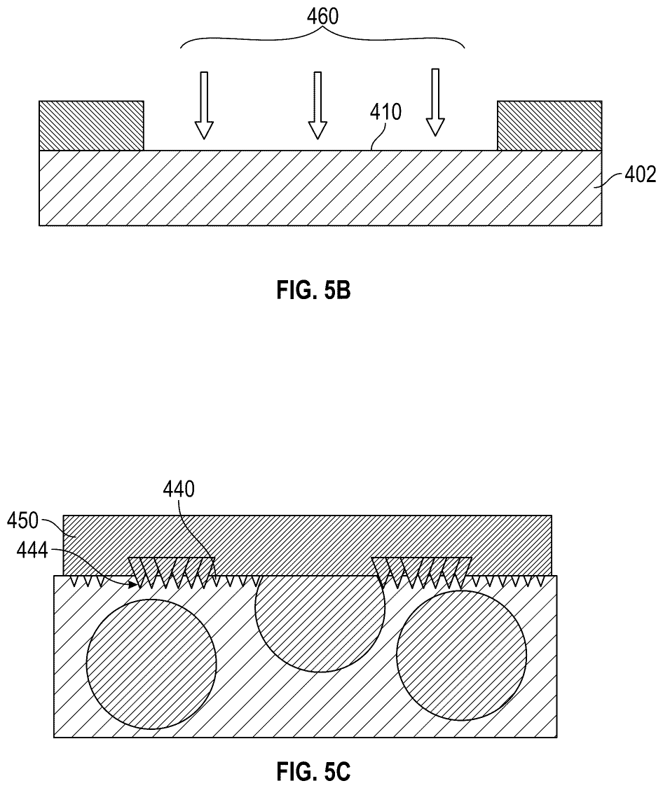

A method of forming recesses 440, as describe above and as illustrated in FIGS. 5A-5C, can include incorporating a plurality of particles, such as sodium ions or magnesium ions 420 into the body 402 of the layer 400. A photoresist 405 can be coupled with the exposed surface 410 to assist in identifying a predetermined location for the incorporation of sodium ions or magnesium ions into the layer. In the example illustrated in FIGS. 5A-5C, the method of roughening a surface can occur at a specific location on the exposed surface 410. In this example, the entire, or majority of, the exposed surface is not subjected to the method discussed below.

The layer 400 can be treated, subjected to, a plurality of sodium ions or magnesium ions 420. The plurality of sodium ions or magnesium ions 420 can be incorporated into the layer 400 and the particles received by the layer 400. For example, the plurality of sodium ions or magnesium ions 420 can penetrate (incorporated) and be absorbed (received) in the exposed surface 410.

The plurality of sodium ions or magnesium ions 420 can be absorbed within an area or location proximate to the exposed surface 410. The plurality of sodium ions or magnesium ions 420 can be absorbed a predetermined distance into the depth of the layer 400, for example, approximately 10 nm to approximately 50 μm. The areas or locations where the sodium ions or magnesium ions 420 are not absorbed is configured to be reactive with further mechanical or chemical processes.

As illustrated in FIG. 5B, a plasma dry etch 460 (herein after “dry etch process”), as an example of a chemical process, can be applied to the exposed surface 410. The dry etch process 460 can be applied to specific or selected location on the exposed surface 410. The dry etch process 460 can be applied at or proximate to locations on the exposed surface 410 indicated by the photoresist 405.

The dry etch process 460 can be reactive with particles in the layer 400, such as particles at, on or proximate to the exposed surface 410. For example, the dry etch process 460 can be reactive with particles surrounding locations where the plurality of sodium ions or the plurality of magnesium ions have been absorbed. The reaction between the dry etch process 460 and the particles surrounding locations where the plurality of sodium ions or the plurality of magnesium ions has been absorbed can cause the particles to be removed from the exposed surface 410.

As illustrated in FIG. 5C, recesses 440 can be formed in the exposed surface 410 where the dry etch process 460 reacted with the particles. The recesses 440 can be irregularly formed with each having profiles of different depths and widths. The recesses 440 can be uniform if the plurality of sodium ions or the plurality of magnesium ions has been absorbed substantially equally throughout the location. The recesses 440 can be configured to be at least one anchoring point for a downstream material 450.

In an example, the downstream material 450 can be coupled to the exposed surface 410 at or proximate to the location where the dry etch process 460 was applied. The downstream material 450 can be coupled, adhered, connected or the like with the exposed surface 410 with mechanical forces, such as compression. The downstream material 450 can be coupled with the exposed surface 410 with an adhesive, such as an epoxy or adhesion promotor.

If an adhesive is used, it can be applied to the exposed surface 410 before applying the downstream material 450. The adhesive can fill or partially fill at least one of the recesses 440.

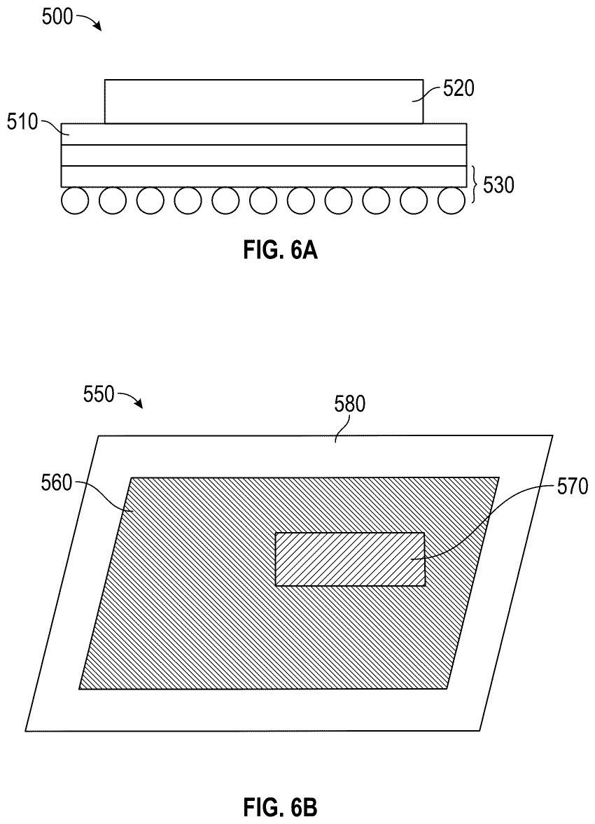

As illustrated in system 500 of FIG. 6A, the layer 510 with a roughened surface can be coupled on a first, or top, side with a downstream material 520. The downstream material 520 can be a material such as a dielectric material, a subsequent layer, or another material which is coupled or adhered to, for example, the majority of the roughened surface, as contemplated by the process using CMP. The second side of the layer 510 can be coupled on a second side, or lower side, with a substrate, or subsequent layer 530.

As illustrated in system 550 of FIG. 6B, the layer 560 with a roughened exposed surface can be coupled on a first, or top, side with a downstream material 570. The downstream material 570 can be a second material such as a solder resist, another polymer material, or the like, which is coupled or adhered to, for example a selected location of the roughened surface, as contemplated by the process using dry etching. A second, or lower, 580 can be coupled with a substrate, subsequent layer, or the like 580.

The recesses 440, either filled with an adhesive or mechanically coupled, can provide improved adhesion between the layer 400 and the downstream material 450.

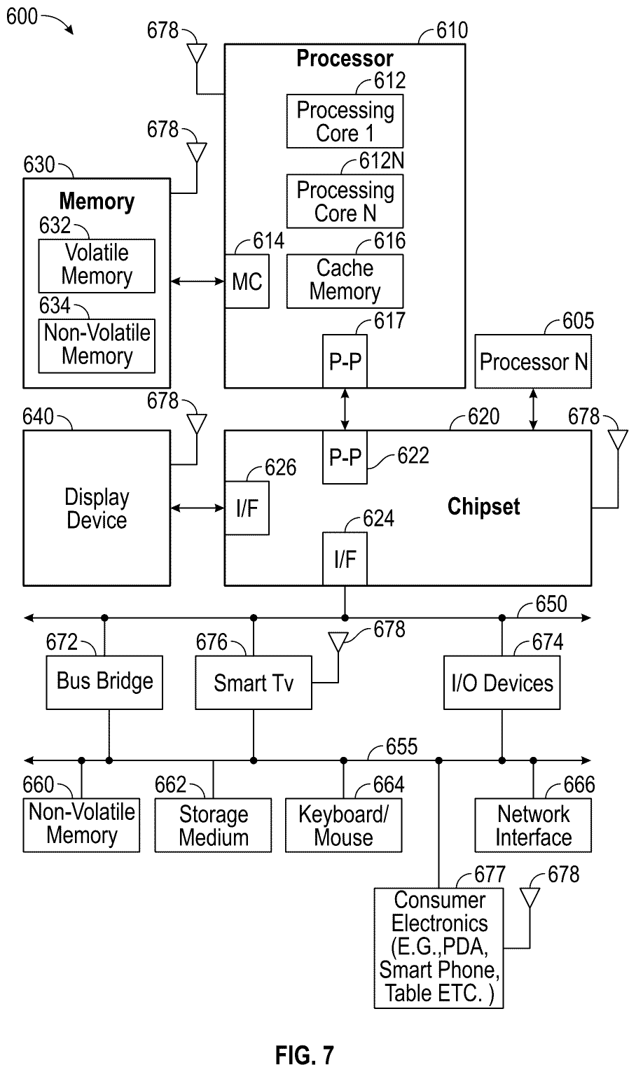

FIG. 7 illustrates a system level diagram, depicting an example of an electronic device (e.g., system) that may include an electronic system, for example, from any of the example process flows described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 includes a system on a chip (SOC) system.

In one embodiment, processor 610 has one or more processor cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices, including a bus bridge 672, a smart TV 676, I/O devices 674, nonvolatile memory 660, a storage medium (such as one or more mass storage devices) 662, a keyboard/mouse 664, a network interface 666, and various forms of consumer electronics 677 (such as a PDA, smart phone, tablet etc.), etc. In one embodiment, chipset 620 couples with these devices through an interface 624. Chipset 620 may also be coupled to a wireless antenna 678 to communicate with any device configured to transmit and/or receive wireless signals. In one example, any combination of components in a chipset may be separated by a continuous flexible shield as described in the present disclosure.

Chipset 620 connects to display device 640 via interface 626. Display 640 may be, for example, a liquid crystal display (LCD), a light emitting diode (LED) array, an organic light emitting diode (OLED) array, or any other form of visual display device. In some embodiments of the example system, processor 610 and chipset 620 are merged into a single SOC. In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

### Various Notes and Aspects

Aspect 1 can include an electrical device including at least one layer, the electrical device comprises the at least one layer including a number of organic particles and an exposed surface on the at least one layer. The number of organic particles includes a first plurality organic particles proximate to the exposed surface. The exposed surface has at least one surface feature characterized by a geometry of removed organic particles.

Aspect 2 can include, or can optionally be combined with the subject matter of Aspect 1, to optionally include the geometry of removed particles forming plurality of recesses in the exposed surface.

Aspect 3 can include, or can optionally be combined with the subject matter of Aspect 1 or Aspect 2, to optionally include the at least one layer formed from a polymer.

Aspect 4 can include, or can optionally be combined with the subject matter of Aspects 1-3, to optionally include the bulk organic particles including nano-size, hydrophilic organic particles.

Aspect 5 can include, or can optionally be combined with the subject matter of Aspects 1-4, to optionally include the geometry of removed particles forms at least one anchoring location on the exposed surface.

Aspect 6 can include, or can optionally be combined with the subject matter of Aspects 1-5, to optionally include the exposed surface configured to support a downstream material and the downstream material coupled with the exposed surface at the at least one anchoring location.

Aspect 7 can include an electrical system including at least one layer, comprising an exposed surface on the at least one layer and a plurality of sodium ions or a plurality of magnesium. The exposed surface has at least a first area and a second area. The first area of the exposed surface is contacted by at least one of the plurality of sodium ions or the plurality of magnesium. The at least one of the plurality of sodium ions or the plurality of magnesium is absorbed into selected locations within the first area. The first area has a surface roughness greater than the second area.

Aspect 8 can include, or can optionally be combined with the subject matter of Aspect 7, to optionally include material surrounding the selected locations where the plurality of sodium ions or plurality of magnesium ions has been absorbed is removed when the selected area is exposed to plasma dry etching.

Aspect 9 can include, or can optionally be combined with the subject matter of Aspect 7 or Aspect 8, to optionally include the at least one layer is formed from a polymer material.

Aspect 10 can include, or can optionally be combined with the subject matter of Aspects 7-9, to optionally include locations of the first area are configured to have a plurality of anchor points.

Aspect 11 can include, or can optionally be combined with the subject matter of Aspects 7-10, to optionally include the layer is a solder resist.

Aspect 12 can include, or can optionally be combined with the subject matter of Aspects 7-11, to optionally include a substrate coupled to one of the at least one layer surface.

Aspect 13 can include a method for forming an irregular surface on a layer for an electrical system. The method comprising incorporating a plurality of particles into the layer. The plurality of particles is received within the layer. Applying at least one of mechanical force or chemical reaction to an exposed surface of the layer. Removing select particles from the exposed surface with the mechanical force or the chemical reaction. Removing selected particles forms recesses within the exposed surface.

Aspect 14 can include, or can optionally be combined with the subject matter of Aspect 13, to optionally include coupling the layer to at least one of a die package or a substrate.

Aspect 15 can include, or can optionally be combined with the subject matter of Aspect 13 or Aspect 14, to optionally include a geometry of removed organic particles is configured to be anchor points in the layer.

Aspect 16 can include, or can optionally be combined with the subject matter of Aspects 13-15, to optionally include subjecting the layer to the plurality of particles includes incorporating organic fillers into the layer.

Aspect 17 can include, or can optionally be combined with the subject matter of Aspects 13-16, to optionally include applying chemical-mechanical polishing to the exposed surface. Removing the organic fillers from the exposed surface. Where removing the organic fillers forms recesses within the exposed surface.

Aspect 18 can include, or can optionally be combined with the subject matter of Aspects 13-17, to optionally include incorporating the plurality of particles includes applying at least one of a plurality of sodium ions or a plurality of magnesium on selected areas of the exposed surface.

Aspect 19 can include, or can optionally be combined with the subject matter of Aspects 13-18, to optionally include the plurality of sodium ion or the plurality of magnesium ions are absorbed into the layer. Applying dry plasma etching to the selected areas. Removing the select particles surrounding locations where the plurality of sodium ions or the plurality of magnesium ions has been absorbed and forming recesses within the exposed surface.

Aspect 20 can include, or can optionally be combined with the subject matter of Aspects 13-19, to optionally include the removing select particles forms a roughened surface configured to be at least one anchoring point.

Each of these non-limiting aspects can stand on its own, or can be combined in various permutations or combinations with one or more of the other aspects.

The above description includes references to the accompanying drawings, which form a part of the detailed description. The drawings show, by way of illustration, specific embodiments in which the invention can be practiced. These embodiments are also referred to herein as “aspects” or “examples.” Such aspects or example can include elements in addition to those shown or described. However, the present inventors also contemplate aspects or examples in which only those elements shown or described are provided. Moreover, the present inventors also contemplate aspects or examples using any combination or permutation of those elements shown or described (or one or more features thereof), either with respect to a particular aspects or examples (or one or more features thereof), or with respect to other Aspects (or one or more features thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

The above description is intended to be illustrative, and not restrictive. For example, the above-described aspects or examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as aspects, examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. An electrical device including at least one layer, comprising:
the at least one layer including a number of organic particles; and
an exposed surface on the at least one layer;
wherein the number of organic particles includes a first plurality organic particles proximate to the exposed surface;
wherein the exposed surface has at least one surface feature characterized by a geometry of removed organic particles.

2. The electrical device of claim 1, wherein the geometry of removed particles forms plurality of recesses in the exposed surface.

3. The electrical device of claim 1 wherein the at least one layer is formed from a polymer.

4. The electrical device of claim 1, wherein the organic particles includes nano-size organic particles.

5. The electrical device of claim 1, wherein the geometry of removed particles forms at least one anchoring location on the exposed surface.

6. The electrical device of claim 5, wherein the exposed surface is configured to support a downstream material;
wherein the downstream material is coupled with the exposed surface at the at least one anchoring location; and
wherein the layer with the downstream material is coupled to at least one of a die package or a substrate.

7. An electrical system including at least one layer, comprising:
an exposed surface on the at least one layer;
wherein the exposed surface has at least a first area and a second area;
a plurality of sodium ions or a plurality of magnesium ions;
wherein the first area of the exposed surface is contacted by at least one of the plurality of sodium ions or the plurality of magnesium ions;
wherein the at least one of the plurality of sodium ions or the plurality of magnesium ions is absorbed into selected locations within the first area;
wherein the first area has a surface roughness greater than the second area.

8. The electrical system of claim 7, wherein material surrounding the selected locations where the plurality of sodium ions or plurality of magnesium ions has been absorbed is removed when the selected area is exposed to plasma dry etching.

9. The electrical system of claim 7 wherein the at least one layer is formed from a polymer material.

10. The electrical system of claim 7, wherein locations of the first area are configured to have a plurality of anchor points.

11. The electrical system of claim 10, wherein the at least one layer is a solder resist.

12. The electrical system of claim 7, further comprising at least one of a die package or substrate coupled to one of the at least one layer.

13. A method for forming an irregular surface on a layer for an electrical system, the method comprising:
incorporating a plurality of particles into the layer;
wherein the plurality of particles is received within the layer;
applying at least one of mechanical force or chemical reaction to an exposed surface of the layer; and
removing select particles from the exposed surface with the mechanical force or the chemical reaction;
wherein removing selected particles forms recesses within the exposed surface.

14. The method of claim 13, further comprising:
coupling the layer to at least one of a die package or a substrate.

15. The method of claim 13 wherein a geometry of removed organic particles is configured to be anchor points in the layer.

16. The method of claim 13 wherein subjecting the layer to the plurality of particles includes incorporating organic fillers into the layer.

17. The method of claim 16 further comprising:
applying chemical-mechanical polishing to the exposed surface; and
removing the organic fillers from the exposed surface;
wherein removing the organic fillers forms at least one recess within the exposed surface.

18. The method of claim 13 wherein incorporating the plurality of particles includes applying at least one of a plurality of sodium ions or a plurality of magnesium on selected areas of the exposed surface.

19. The method of claim 18 wherein the plurality of sodium ion or the plurality of magnesium ions are absorbed into the layer; s
applying dry plasma etching to the selected areas;
removing the select particles surrounding locations where the plurality of sodium ions or the plurality of magnesium ions has been absorbed; and
forming recesses within the exposed surface.

20. The method of claim 18 wherein the removing select particles forms a roughened surface configured to be at least one anchoring point.
